(19) United States
(12) Patent Application Publication
(10) Pub. No.: US 2025/0056711 A1
(43) Pub. Date: Feb. 13, 2025

(54) CONNECTOR STRUCTURES

(71) Applicant: Cisco Technology, Inc., San Jose, CA (US)

(72) Inventors: D. Brice Achkir, Livermore, CA (US); Hanqin Ye, Shanghai (CN); Michael J. Umina, Newton, MA (US)

(21) Appl. No.: 18/447,406

(22) Filed: Aug. 10, 2023

(51) Int. Cl. H05K 1/02; H05K 1/11

(52) U.S. Cl. CPC H05K 1/0228; H05K 1/0215; H05K 1/11; H05K 2201/09227

(57) ABSTRACT

In some aspects, the techniques described herein relate to an apparatus including: a printed circuit board connector structure, comprising: an outer ground defining a receiving area; and a pair of traces located in the receiving area, the pair of traces collectively having a first side, a second side, a third side, and a fourth side, wherein the outer ground extends around each of the first side, the second side, and the third side of the pair of traces.

### TECHNICAL FIELD

The present disclosure relates to printed circuit board (PCB) connector structures, and particularly to vertical connector structures in a PCB.

### BACKGROUND

Vertical conductive structures are an interconnect technique used in a PCB to overcome limitations associated with VIA connection transitions. Vertical conductive structures and VIAs are different types of connector structures. VIA connections are cylindrically shaped interconnects used in PCBs. Vertical conductive structures utilize traces that are oriented in the orthogonal direction of the PCB layer stack. In some implementations, a ball grid array (BGA) pad is connected to the top of a vertical conductive structure trace.

### BRIEF DESCRIPTION OF THE DRAWINGS

FIG. 1 is an overhead view of a PCB that includes vertical interconnect structures of the techniques disclosed herein, according to an example embodiment.

FIG. 2 is a side view of the PCB illustrated in FIG. 1, according to an example embodiment.

FIG. 3 is a cross-sectional perspective view of the PCB illustrated in FIG. 1 taken along the line “A”-“A” in FIG. 1, according to an example embodiment.

FIG. 4 is a cross-sectional overhead perspective view of the PCB illustrated in FIG. 2 taken along the line “B”-“B” in FIG. 2, according to an example embodiment.

FIG. 5 illustrates steps of a fabrication process for a related art interconnect structure and an exemplary method of fabrication steps of an interconnect structure according to an example embodiment of the disclosed techniques.

FIG. 6 is a perspective view of an interconnect structure implementing the disclosed techniques, according to an example embodiment.

FIG. 7 includes overhead views of a related art interconnect structure and an interconnect structure implementing the disclosed techniques, according to an example embodiment.

FIG. 8 is a graph of crosstalk performance of near end crosstalk (NEXT) signals in decibels associated with a related art interconnect structure and an interconnect structure implementing the disclosed techniques, according to an example embodiment.

FIG. 9 is a graph of crosstalk performance of far end crosstalk (FEXT) signals in decibels associated with a related art interconnect structure and interconnect structure implementing the disclosed techniques, according to an example embodiment.

FIG. 10 is a graph of signal integrity in terms of Insertion Loss (IL) in decibels associated with a related art interconnect structure and an interconnect structure implementing the disclosed techniques, according to an example embodiment.

FIG. 11 is a graph of signal integrity in terms of Return Loss (RL) in decibels associated with a related art interconnect structure and an interconnect structure implementing the disclosed techniques, according to an example embodiment.

FIG. 12 is an overhead view of another example of a PCB that includes vertical interconnect structures implementing the disclosed techniques, according to an example embodiment.

FIG. 13 is a cross-sectional perspective view of the PCB illustrated in FIG. 12 taken along the line “C”-“C” in FIG. 12, according to an example embodiment.

FIG. 14 is a cross-sectional overhead view of the PCB illustrated in FIG. 12 taken along a line similar to line “B”-“B” in FIG. 2, according to an example embodiment.

FIG. 15 illustrates manufacturing steps of a method of manufacturing steps of an interconnect structure of the disclosed techniques, according to an example embodiment.

FIG. 16 is a perspective view of an intermediate configuration of an interconnect structure implementing the disclosed techniques, according to an example embodiment.

FIG. 17 is a perspective view of an interconnect implementing the disclosed techniques, according to an example embodiment.

FIG. 18 includes overhead views of the related art interconnect structure and the interconnect structure according to disclosed techniques that are illustrated in FIG. 7, along with another interconnect structure implementing the disclosed techniques, according to an example embodiment.

FIG. 19 is a graph of crosstalk performance of NEXT signals in decibels associated with a related art interconnect structure and multiple interconnect structures implementing the disclosed techniques, according to example embodiments.

FIG. 20 is a graph of crosstalk performance of FEXT signals in decibels associated with a related art interconnect structure and multiple interconnect structures implementing the disclosed techniques, according to example embodiments.

FIG. 21 is a graph of signal integrity in terms of IL in decibels associated with a related art interconnect structure and multiple interconnect structures implementing the disclosed techniques, according to example embodiments.

FIG. 22 is a graph of signal integrity in terms of RL in decibels associated with a related art interconnect structure and interconnect structures implementing the disclosed techniques, according to example embodiments.

FIG. 23 is a graph of impedance measured for a related art interconnect structure and multiple interconnect structures implementing the disclosed techniques, according to example embodiments.

### DETAILED DESCRIPTION

### Overview

In some aspects, the techniques described herein relate to an apparatus including: a printed circuit board connector structure, comprising: an outer ground defining a receiving area; and a pair of traces located in the receiving area, the pair of traces collectively having a first side, a second side, a third side, and a fourth side, wherein the outer ground extends around each of the first side, the second side, and the third side of the pair of traces.

In some aspects, the techniques described herein relate to an apparatus including: a printed circuit board connector structure, comprising: an outer ground defining a receiving area; a first trace located in the receiving area, the first trace having a first side and a second side opposite to the first side; and a second trace spaced apart from the first trace, the second trace located in the receiving area, the second trace having a third side and a fourth side opposite to the third side, the fourth side of the second trace being proximate to the second side of the first trace, wherein the outer ground extends around the first side of the first trace and around the third side of the second trace.

In some aspects, the techniques described herein relate to an apparatus including: a printed circuit board connector structure, comprising: a first outer ground defining a first receiving area; and a first pair of vertical traces located in the first receiving area, the first pair of vertical traces collectively having a first side, a second side, a third side, and a fourth side, wherein the first outer ground extends around each of the first side, the second side, and the third side of the first pair of vertical traces; and a second connector structure including: a second outer ground defining a second receiving area; and a second pair of vertical traces located in the second receiving area, the second pair of vertical traces collectively having a fifth side, a sixth side, a seventh side, and an eighth side, wherein the second outer ground extends around each of the fifth side, the sixth side, and the seventh side of the second pair of vertical traces, wherein the first outer ground and the second outer ground reduce any signals leaving the first receiving area and the second receiving area, respectively.

### Example Embodiments

Vertical conductive structures increase the routing density by reducing the quantity of layers needed for high speed and power lanes compared to standard VIA connections. Vertical conductive structures also improve signal performance by having more ground wrapping the signal area. In addition, vertical conductive structures reduce fabrication costs when using a high density interconnect (HDI) process that requires sequential build up steps. However, related art vertical conductive structures have limitations.

In related art connector structures, the ground wrapping the signal area is limited. Leakage of a signal from the signal area occurs, thereby resulting in reduced signal integrity and increased crosstalk with adjacent connector structures.

Also, in related art connector structures, to connect a stripline to the connector structure, a primary route overshoot is performed and an anti-pad is created under the connector structure to avoid any shorting of the reference/ground plane with the traces of a connector structure. The overshoot under the stripline plane create an L-shaped stub resulting in resonances. To try to avoid the shorting of the L-shaped stub with the reference plane, a thicker dielectric material would be used. However, that results in an increase of the overall stackup and unbalanced stripling traces, thereby increasing overall costs and preventing any routing under the connector structure location.

There is a desire to reduce pair-to-pair crosstalk between adjacent vertical conductive or connector structures caused by leakage of a signal due to the short ground wrap of the vertical conductive structures. In addition, there a benefits to a vertical conductive structure that avoids shorting of the reference or ground plane of the vertical conductive structure with its traces.

The example embodiments of vertical conductive structures disclosed herein may address the multiple challenges identified above. The example embodiments reduce pair-to-pair crosstalk between adjacent vertical conductive structures caused by leakage of a signal due to the short ground wrap of the vertical conductive structures. In addition, the example embodiments may avoid the shorting of the reference or ground plane of a vertical conductive structure with its traces.

In a first example embodiment of a vertical conductive structure according to the techniques disclosed herein, the vertical conductive structure increases the density of routing in the BGA area of a PCB. In addition, the vertical conductive structure provides a good current return path for a vertical or orthogonal signal. Also, the vertical conductive structure reduces the signal coupling between adjacent vertical signal pairs of traces.

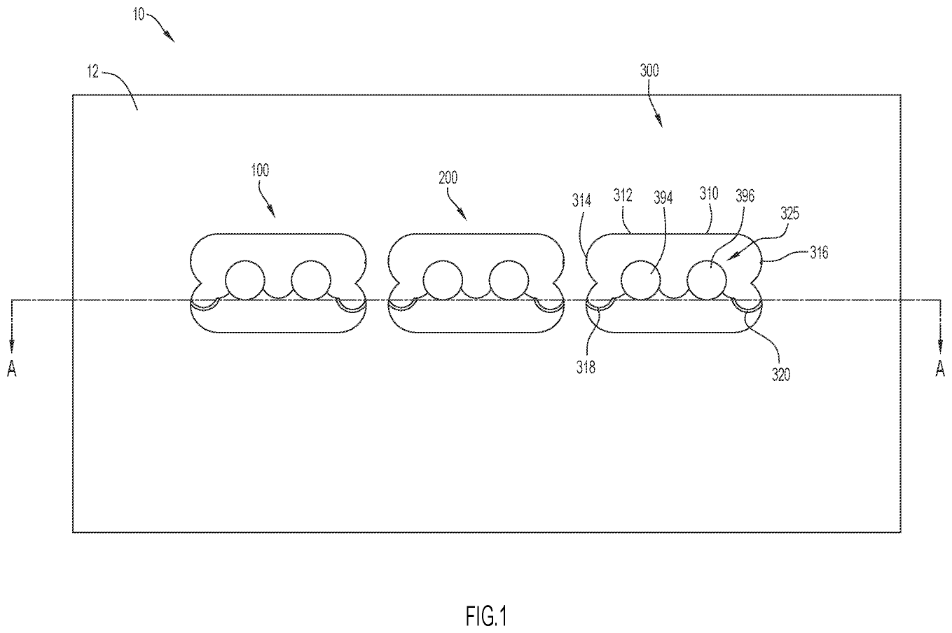

Turning to FIG. 1, an overhead view of an example embodiment of a PCB that includes vertical interconnect structures according to the disclosed techniques is illustrated. In this embodiment, the PCB 10 includes an upper surface 12. It is to be understood that the shape and size of the PCB 10 is exemplary only, and that in different embodiments, the PCB shape and size can vary. In addition, PCB 10 being illustrated with three vertical interconnect structures, which are described in detail below, is only exemplary, and in different embodiments, the quantity and location of vertical interconnect structures in a PCB can vary.

In this embodiment, PCB 10 includes connector structure 100, connector structure 200, and connector structure 300. The features of connector structure 300 are illustrated and discussed in detail relative to FIGS. 1-7. It is to be understood that each of connector structure 100 and connector structure 200 has similar features to those of connector structure 300. Accordingly, the description of connector structure 300 applies to connector structure 100 and connector structure 200 as well.

Referring to FIG. 1, connector structure 300 includes an outer ground or return 310 that has an intermediate portion 312, a side portion 314 coupled to one end of the intermediate portion 312, and another side portion 316 coupled to an opposite end of the intermediate portion 312. As shown, both of the side portions 314 and 316 are curved and are directed inwardly. Coupled to an end of side portion 314 is an end or end portion 318. End portion 318 is a curved end that extends inwardly and in the direction of the opposite side of the outer ground 310. Coupled an end of side portion 316 is an end or end portion 320. End portion 320 is a curved end that extends inwardly and in the direction of end portion 318.

The intermediate portion 312, the side portions 314 and 316, and the end portions 318 and 320 collectively define a signal area or a receiving area 325 in which the traces of connector structure 300 are located. In one embodiment, area 325 includes resin that is located inside the area defined by the ground 310. The end portions 318 and 320 extend beyond the location of the traces, as described in detail below. Each of the end portions 318 and 320 reduces the signals leaving area 325 of the connector structure 300 due to its extension beyond the traces of connector structure 300 and due to its curved configuration. Also shown in FIG. 1 is a pair of BGA pads. BGA pad 394 is connected to a trace in connector structure 300. Similarly, BGA pad 396 is connected to a trace in connector structure 300.

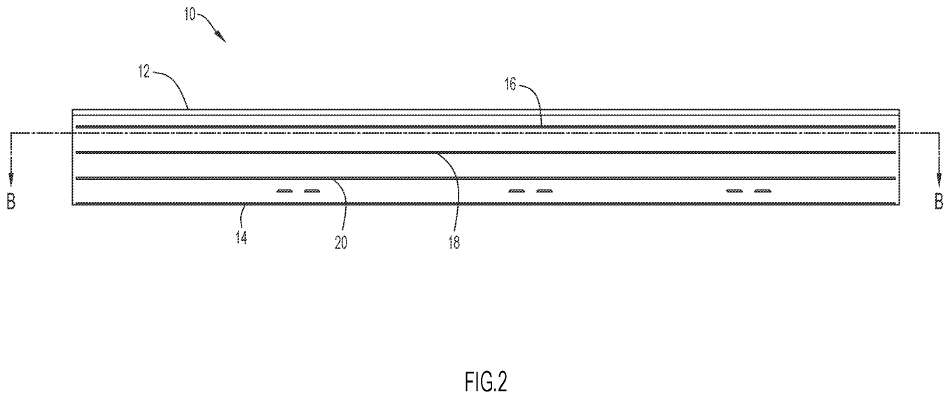

Turning to FIG. 2, a side view of the PCB illustrated in FIG. 1 is illustrated. In this view, the various levels of this example embodiment of a PCB are shown. In this embodiment, PCB 10 includes an upper surface 12, a lower surface 14, and multiple layers 16, 18, and 20 located therebetween.

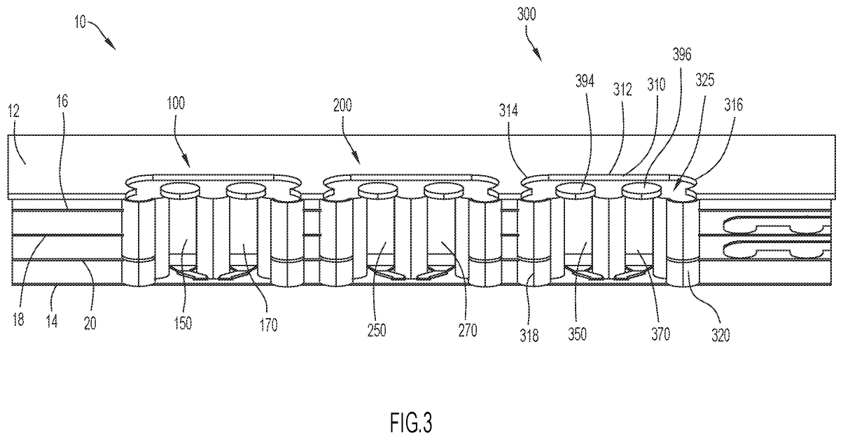

Referring to FIG. 3, a cross-sectional perspective view of PCB 10 taken along the line “A”-“A” in FIG. 1 is illustrated. The plane at which the cross-sectional view is taken is slightly in front of the connector structures 100, 200, and 300, thereby enabling the view of them.

As shown, connector structure 100 includes a pair of traces, which includes trace 150 and trace 170. Traces 150 and 170 extend in an orthogonal direction of PCB 10, which may be referred to herein alternatively as a vertical direction. Each of the traces 150 and 170 has a BGA pad connected to one of its ends, which in this embodiment can be referred to as an upper end of the traces. Similarly, connector structure 200 includes a pair of traces, which includes traces 250 and trace 270. Traces 250 and 270 also extend in an orthogonal or vertical direction in the PCB 10. Also, each of the traces 350 and 270 includes a BGA pad connected to one of its ends.

Turning to connector structure 300, its features are described in detail starting with those illustrated in FIG. 3. As mentioned above, the description of features of connector structure 300 apply to similar features of connector structures 100 and 200 in this embodiment.

Connector structure 300 includes a pair of traces, which includes traces 350 and 370. Traces 350 and 370 extend vertically and have BGA pads 394 and 396 connected thereto, respectively. The ground 310 of connector structure 300 is illustrated in FIG. 3. The intermediate portion 312 and the side portions 314 and 316 extend around the back and sides of the pair of traces 350 and 370. End portion 318 with its curved configuration is oriented inwardly and back toward the traces 350 and 370. Similarly, end portion 320 with its curved configuration is oriented inwardly and back toward the traces 350 and 370. End portions 318 and 320 are directed generally toward each other and toward the corresponding one of the side portions 314 and 316. The locations of the end portions 318 and 320 are such that they block some of the signals from traces 350 and 370 from leaving area 325. In addition, the curved configuration of each of end portions 318 and 320 blocks some of the signals from traces 350 and 370 from leaving area 325.

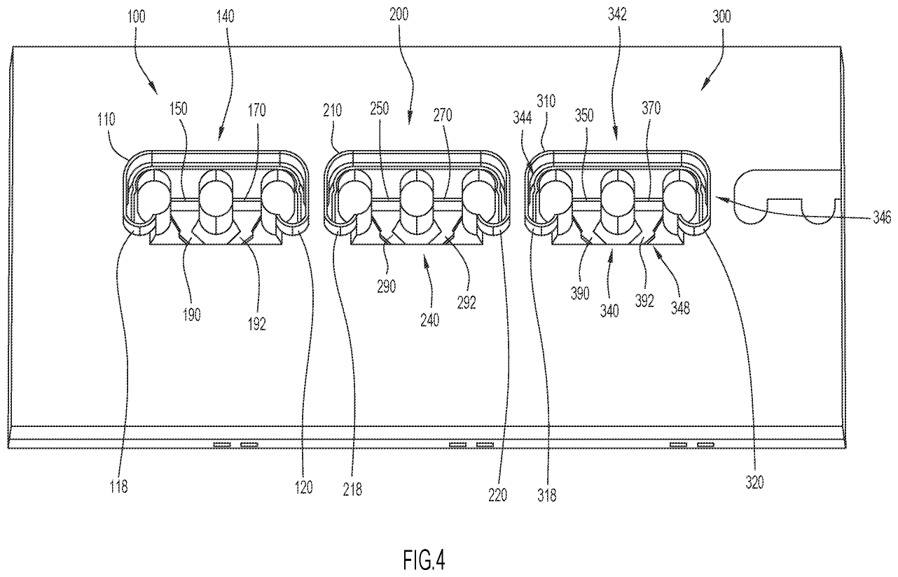

Turning to FIG. 4, a cross-sectional overhead perspective view of PCB 10 taken along the line “B”-“B” in FIG. 2 is illustrated. This view is of a slightly different angle than the view illustrated in FIG. 3.

Referring to connector structure 100, its ground 110 with opposite curved end portions 118 and 120 is shown. Ground 110 surrounds three sides of the pair 140 of traces located therein, namely three sides of traces 150 and 170. Vertical or orthogonal trace 150 is connected to horizontal trace 190. Similarly, vertical or orthogonal trace 170 is connected to horizontal trace 192. The end portions 118 and 120 of ground 110 reduce the leakage of signals from traces 150 and 170. This reduction of signal leakage results in less interference of the signal or signals from connector structure 100 with the signal or signals generated by the adjacent connector structure 200.

In FIG. 4, the ground 210 of connector structure 200 is shown with its opposite curved end portions 218 and 220. Ground 210 surrounds three sides of the pair 240 of traces located therein, namely three sides of traces 250 and 270. In this embodiment, vertical trace 250 is connected to horizontal trace 290, and vertical trace 270 is connected to horizontal trace 292. The end portions 218 and 220 of ground 210 reduce the leakage of signals from traces 250 and 270. This reduction of signal leakage by ground 210 results in less interference of the signal or signals from connector structure 200 with the signal or signals generated by each of the adjacent connector structures 100 and 300.

Referring to connector structure 300, it includes a pair 340 of traces (traces 350 and 370) located therein. The pair 340 of traces has four sides 342, 344, 346, and 348. In this embodiment, ground 310 surrounds three sides of the trace pair 340, namely, sides 342, 344, and 346. As shown, the sides 342, and 344, and 346 of the trace pair 340 are completely surrounded by the ground 310.

Vertical trace 350 is connected to horizontal trace 390, and vertical trace 370 is connected to horizontal trace 392. The curved end portions 318 and 320 of the ground 310 of connector structure 300 extend toward each other and the opposite sides of the ground 310. The end portions 318 and 320 of ground 310 reduce the leakage of signals from traces 350 and 370. This reduction of signal leakage by ground 310 results in less interference of the signal or signals from connector structure 300 with the signal or signals generated by adjacent connector structure 200.

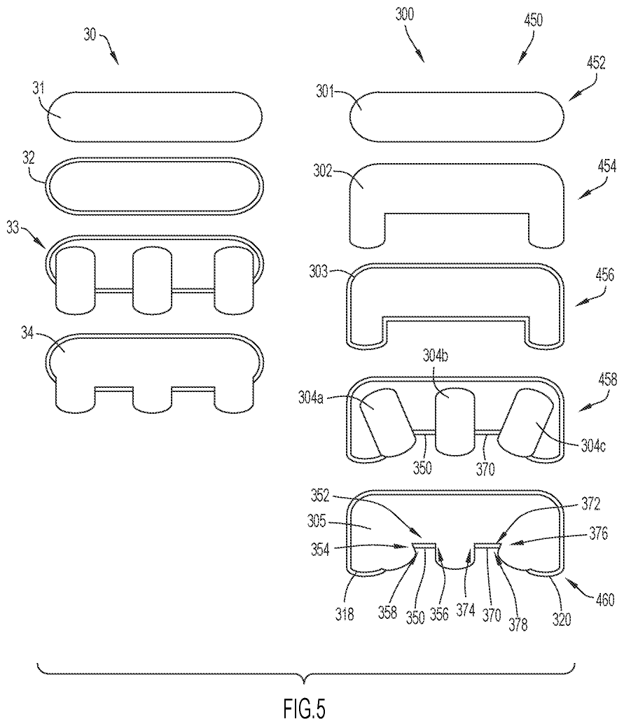

Turning to FIG. 5, the fabrication or manufacturing steps of a related art interconnect structure and an exemplary method of fabricating or manufacturing an interconnect structure according to the disclosed techniques are illustrated. Connector structure 30 is an example of various steps to manufacture a related art interconnect structure. The first step to manufacture connector structure 30 is to form a primary routing 31. A plating 32 is applied to the primary routing 31 around the perimeter thereof. Cross routes 33 are formed, thereby creating a pair of traces. A resin filling 34 is then inserted in the area.

The exemplary method 450 of fabricating connector structure 300 illustrated in FIG. 5 is described. In step 452, a first primary routing 301 is formed in the shape illustrated. In step 454, a second primary routing 302 is formed in the shape illustrated. The second primary routing 302 is located on top of the first primary routing 301. In step 456, a plating 303 is placed around the perimeter of the second primary routing 302.

In step 458, several cross routes are formed. In particular, cross routes 304a, 304b, and 304c are formed with cross routes 304a and 304c being oriented such that their longitudinal axes intersect the longitudinal axis of cross route 304b, which is located between cross routes 304a and 304c. The formation of cross routes 304a, 304b, and 304c result in two spaced apart portions of plating 303, which form vertical traces 350 and 370. In step 460, a resin filling 305 is placed to cover up the second primary routing 302 and the cross routes 304a, 304b, and 304c. The resin filling 305 does not cover the upper ends of the vertical traces 350 and 370. As a result, BGA pads (not shown in FIG. 5) can be connected to the upper ends.

Also shown in FIG. 5 are the various sides of the vertical traces 350 and 370. Trace 350 has a side 352 oriented toward the intermediate portion 312 of ground 310, and another side 358 opposite to side 352. Trace 350 also has a side 356 that is oriented toward trace 370, and another side 354 opposite to side 356. Similarly, trace 370 has a side 372 oriented toward the intermediate portion 312 of ground 310, and another side 378 opposite to side 372. Trace 370 also has a side 374 that is oriented toward trace 350, and another side 376 opposite to side 374. Thus, side 356 of trace 350 is proximate to side 374 of trace 370.

In this embodiment, curved end portion 318 of ground 310 extends beyond trace 350 and inwardly toward the opposite end of ground 310. Similarly, curved end portion 320 of ground 310 extends beyond trace 370 and inwardly toward the opposite end of ground 310. As a result, ground 310 extends around sides 354 and 352 of trace 350 and around sides 376 and 372 of trace 370. Ground 310 extends around the rear side of the pair 340 of traces (trace 350 and trace 370) and around the opposite sides of the pair 340 of traces.

One difference between connector structure 300 and connector structure 30 is the use of two primary routings in connector structure 300. The two primary routings control how well the return plan confines the signals from traces 350 and 370, and eliminate the fringes that leak out and cause cross-talk. Another difference is the cross route locations will determine how much the return plan wrap and the cross routes can be performed obliquely. The second primary routing 302 extends the return or ground 310 to create a stepped signal and ground structure that isolates the signals between adjacent connector structures 100, 200, and 300.

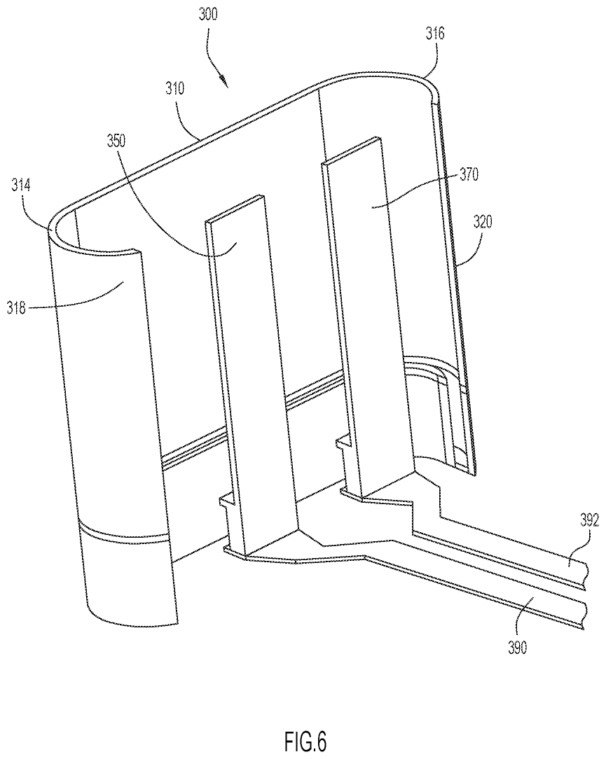

Turning to FIG. 6, a perspective view of an example embodiment of an interconnect structure according to the disclosed techniques is illustrated.

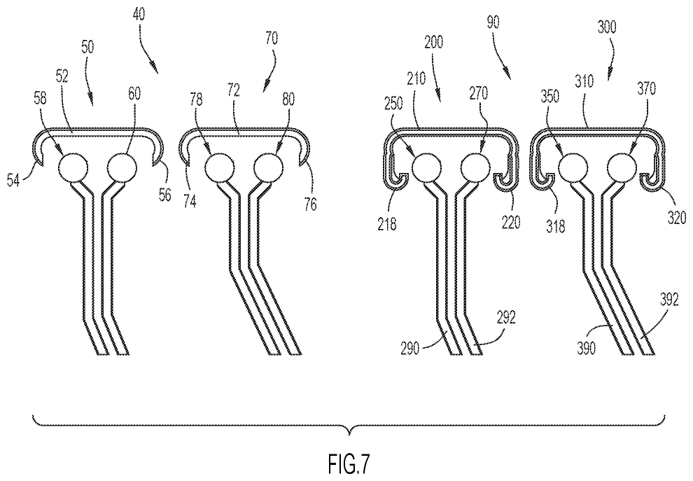

Turning to FIG. 7, overhead views of a related art interconnect structure and an example embodiment of an interconnect structure according to the disclosed techniques are illustrated. The side-by-side arrangement of connector structure system 40 and connector structure system 90 illustrate the differences therebetween.

Connector structure system 40 includes a pair of connector structures 50 and 70. Connector structure 50 includes a ground 52 with ends or end portions 54 and 56 that are opposite to each other. Connector structure 50 also includes traces 58 and 60, which are illustrated with BGA pads connected thereto. Notably, end portion 54 does not extend around the outer side of trace 58, and end portion 56 does not extend around trace 60. As a result, the signals of traces 58 and 60 are not limited by end portions 54 and 56 from leaving the area of the ground 52 and creating signal interference with the signal or signals of connector structure 70.

Connector structure 40 also includes a ground 72 with ends or end portions 74 and 76 that are opposite to each other, and traces 78 and 80, which are illustrated with BGA pads connected thereto. Notably, end portion 74 does not extend around the outer side of trace 78, and end portion 76 does not extend around trace 80. As a result, the signals of traces 78 and 80 are not limited by end portions 74 and 76 from leaving the area of the ground 72 and creating signal interference with the signal or signals of connector structure 50.

Turning to connector structure system 90, it includes connector structures 200 and 300. As previously described, connector structure 200 includes ground 210 with opposite end portions 218 and 220 that surround three sides of the pair of traces 250 and 270. Similarly, connector structure 300 includes ground 310 with opposite end portions 318 and 320 that surround three sides of the pair of traces 350 and 370. The length and configuration of the end portions 218 and 220 and of the end portions 318 and 320 reduce the signals from traces 250 and 270 and from traces 350 and 370, respectively, from leaving the corresponding connector structure 200 or 300.

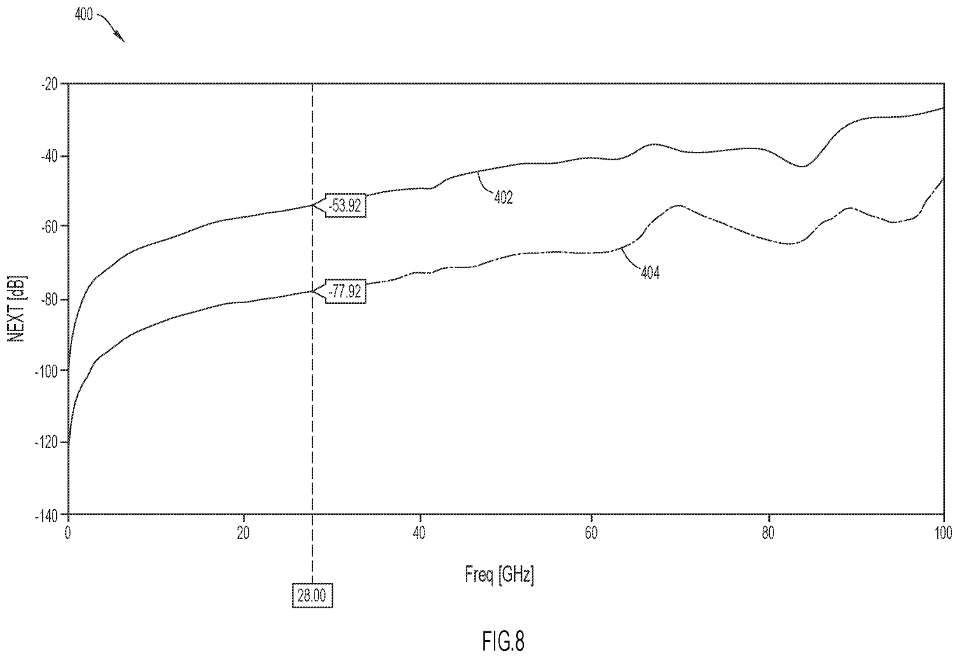

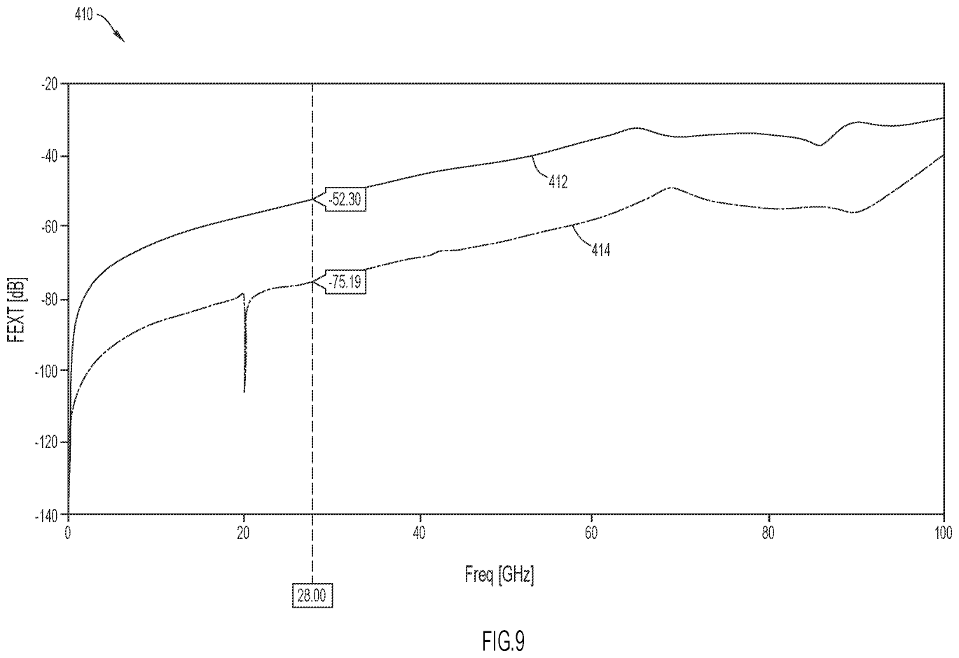

FIGS. 8 and 9 are graphs of signal integrity performance between a related art interconnect structure and an example embodiment of an interconnect structure according to the disclosed techniques.

In FIG. 8, the crosstalk performance of NEXT signals in decibels associated with the different interconnect structures is illustrated. In FIG. 8, graph 400 includes a line 402 that represents the performance associated with a related art interconnect structure (such as connector structure 70 in FIG. 7), and a line 404 that represents the performance associated with an interconnect structure according to the present disclosed techniques (such as connector structure 300 in FIG. 7).

As shown, connector structure 300 improves (by reducing) the crosstalk between adjacent connector structures by approximately 25 dB at the frequency range of 0-100 GHz. In particular, connector structure 300 can achieve −40 dB crosstalk up to 100 GHz. At a frequency of 28 GHz, the measured NEXT for connector structure 300 (line 404) is −77.92 dB, and the measured NEXT for connector structure 70 (line 402) is −53.92 dB. Accordingly, connector structure 300 reduces the NEXT crosstalk as compared to connector structure 70 throughout the frequency range of 0-100 GHz.

In FIG. 9, the crosstalk performance of FEXT signals in decibels associated with the different interconnect structures is illustrated. In FIG. 9, graph 410 includes a line 412 that represents the performance associated with a related art interconnect structure (such as connector structure 70 in FIG. 7), and a line 414 that represents the performance of an interconnect structure according to the disclosed techniques (such as connector structure 300 in FIG. 7).

As shown, connector structure 300 improves (by reducing) the FEXT crosstalk between adjacent connector structures by approximately 25 dB at the frequency range of 0-100 GHz. At a frequency of 28 GHz, the measured FEXT for connector structure 300 (line 414) is −75.19 dB, and the measured FEXT for connector structure 70 (line 412) is −52.30 dB. Accordingly, connector structure 300 reduces the FEXT crosstalk as compared to connector structure 70 throughout the frequency range of 0-100 GHz as well.

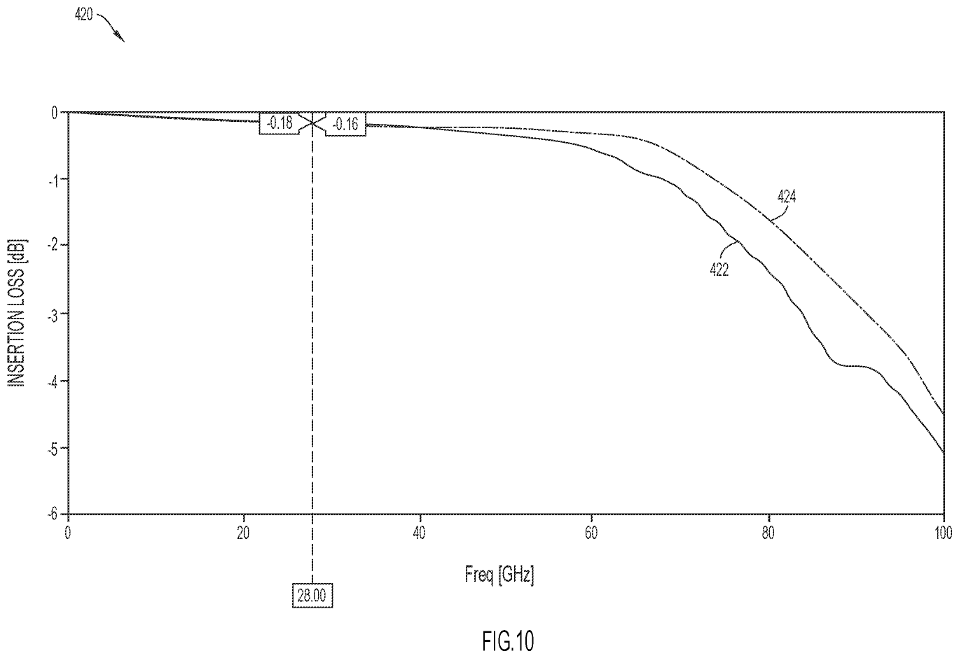

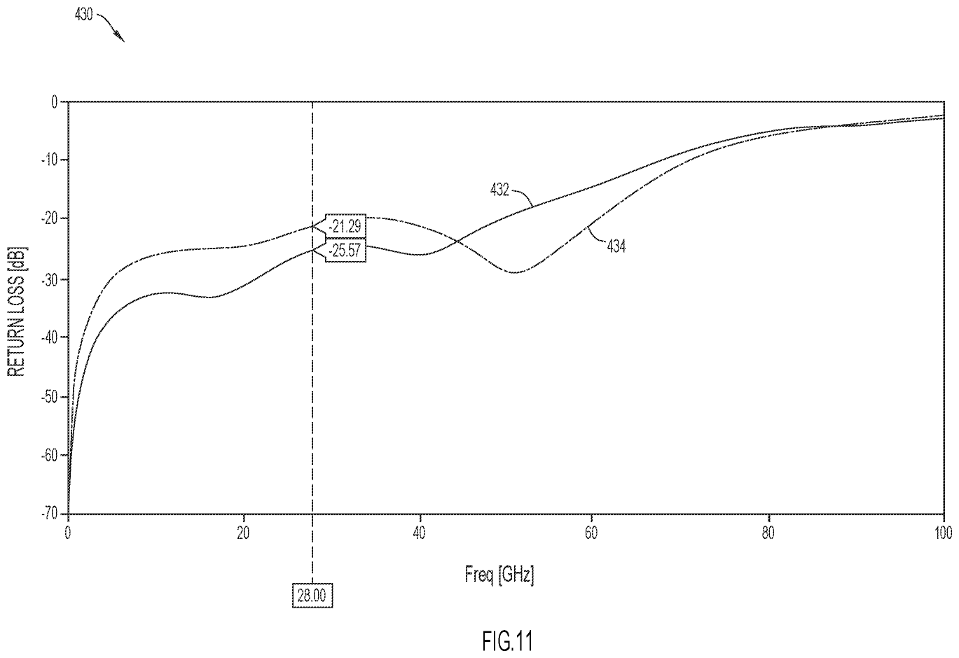

FIGS. 10 and 11 are graphs that show the signal integrity in terms of IL and RL, respectively, for a related art interconnect structure and an example embodiment of an interconnect structure according to the disclosed techniques

In FIG. 10, the signal integrity in terms of IL in decibels associated with the different interconnect structures is illustrated. Graph 420 includes a line 422 that represents the performance associated with a related art interconnect structure (such as connector structure 70 in FIG. 7), and a line 424 that represents the performance associated with an interconnect structure according to the disclosed techniques (such as connector structure 300 in FIG. 7).

As shown, connector structure 300 improves the IL by 1 dB from 50-100 GHz compared to connector structure 70. At a frequency of 28 GHz, the IL for connector structure 300 (line 424) is −0.18 dB, and the IL for connector structure 70 (line 422) is −0.16 dB. However, as the frequency of the signal in the corresponding traces is increased, the IL improvement by connector structure 300 relative to connector structure 70 is illustrated.

In FIG. 11, the signal integrity in terms of RL in decibels associated with the different interconnect structures is illustrated. In FIG. 11, graph 430 includes a line 432 that represents the performance associated with a related art interconnect structure (such as connector structure 70 in FIG. 7), and a line 434 that represents the performance of an interconnect structure according to the disclosed techniques (such as connector structure 300 in FIG. 7).

At a frequency of 28 GHz, the RL for connector structure 300 (line 434) is −21.29 dB, and the RL for connector structure 70 (line 432) is −25.57 dB. However, connector structure 300 can achieve approximately 15 dB RL up to 64 GHz relative to connector structure 70.

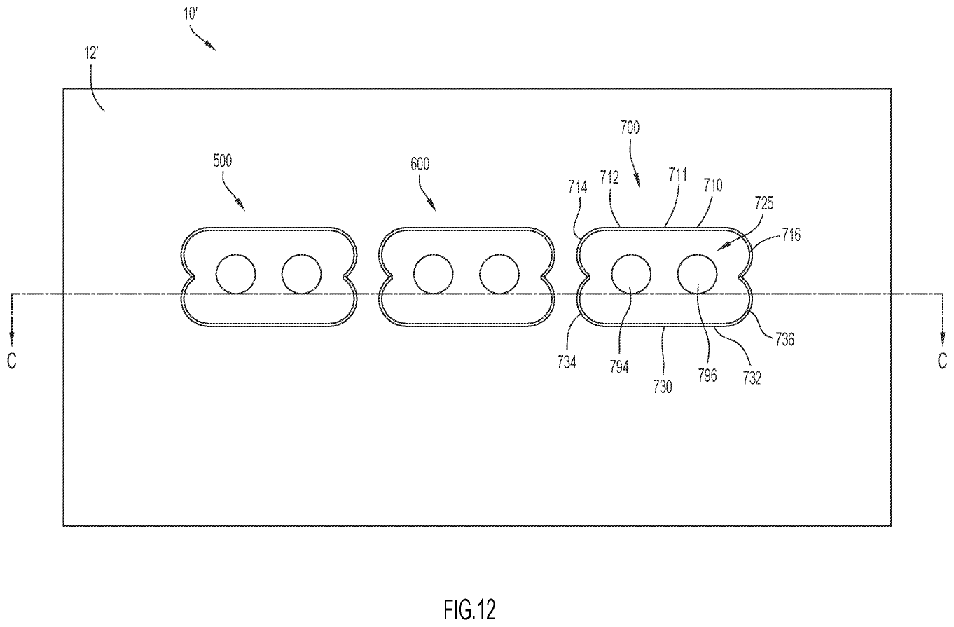

Turning to FIGS. 12-23, another embodiment of an interconnect structure according to the disclosed techniques is illustrated and described. In FIG. 12, an overhead view of an exemplary embodiment of a PCB that includes vertical interconnect structures according to the disclosed techniques is shown.

In this embodiment, PCB 10′ has an upper surface 12. Similar to PCB 10, PCB 10′ can have different shapes and sized, as well as different quantities of interconnect structures, in different embodiments. PCB 10′ includes connector structure 500, connector structure 600, and connector structure 700. The features of connector structure 700 are discussed in detail, and each of connector structure 500 and connector structure 600 has similar features thereto.

Referring to FIG. 12, connector structure 700 includes an outer ground or return 710 that has a portion or a first portion 711 that includes an intermediate portion 712, a side portion 714 coupled to one end of the intermediate portion 712, and another side portion 716 coupled to an opposite end of the intermediate portion 712. As shown, both of the side portions 714 and 716 of first portion 711 are curved. Outer ground 710 also includes another or second portion 730 that is coupled to outer ground 710. Portion 730 also includes an intermediate portion 732, a side portion 734 coupled to one end of the intermediate portion 732, and another side portion 736 coupled to an opposite end of the intermediate portion 732. Both of the side portions 734 and 736 are curved. In addition, side portion 734 is connected to side portion 714, and side portion 736 is connected to side portion 716.

As a result, outer ground 710 forms a receiving area 725 that is surrounded laterally by the various components of the outer ground 710. A pair of traces are located in receiving area 725, which has a resin filling therein surrounding the traces. BGA pads 794 and 796 are connected to ends of the traces. The enclosed configuration of the outer ground 710 reduces the signals leaving area 725 of the connector structure 700.

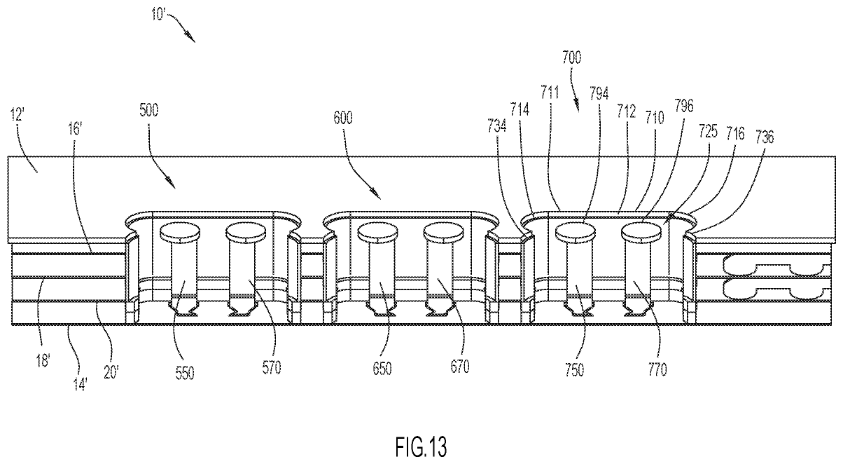

Referring to FIG. 13, a cross-sectional perspective view of PCB 10′ taken along the line “C”-“C” in FIG. 12 is illustrated. The plane at which the cross-sectional view is taken is slightly in front of the connector structures 500, 600, and 700, thereby enabling this view of them. PCB 10′ has an upper surface 12′, a lower surface 14′, and multiple layers 16′, 18′, and 20′ located therebetween. The quantity of layers in PCB 10′ can vary in different embodiments.

As shown, connector structure 500 includes a pair of traces, which includes trace 550 and trace 570. Traces 550 and 570 extend in an orthogonal direction of PCB 10′, which may be referred to as a vertical direction. Each of the traces 550 and 570 has a BGA pad connected to one of its ends. Similarly, connector structure 600 includes a pair of traces, which includes trace 650 and trace 670. Traces 650 and 670 also extend in an orthogonal or vertical direction in the PCB 10′. Also, each of the traces 650 and 670 includes a BGA pad connected thereto.

Turning to connector structure 700, its features are described in detail starting with those illustrated in FIG. 13. Connector structure 700 includes a pair of traces, which includes traces 750 and 770, which extend vertically or orthogonally relative to the PCB 10′. As discussed above, ground 710 includes a portion 711 that has intermediate portion 712 and the side portions 714 and 716 coupled thereto. In this cross-sectional view, only parts of side portions 734 and 736 of portion 730 are shown due to the location of the cross-sectional view.

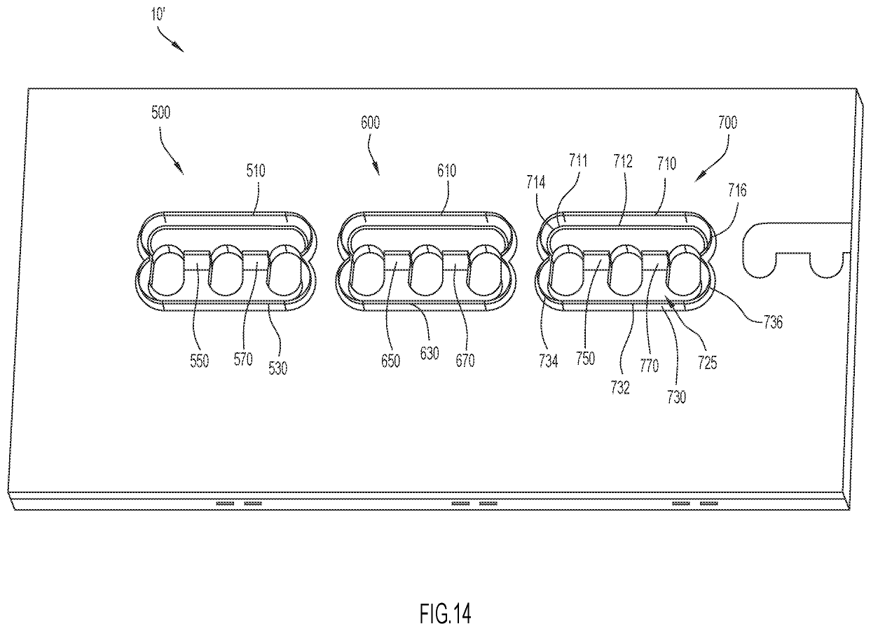

Turning to FIG. 14, a cross-sectional overhead perspective view of PCB 10′ is illustrated. Connector structure 500 has a ground 510 with a portion 530 and forms a receiving area in which a pair of traces (traces 550 and 570) is located. The ground 510 extends around the perimeter of and all four sides of the pair of traces. The surrounding or enclosed configuration of ground 510 around the traces 550 and 570 reduce the leakage of signals from traces 550 and 570, which reduces the interference of the signal or signals from connector structure 500 with the signal or signals generated by the adjacent connector structure 600.

Ground 610 of connector structure 600 has a portion 630 and defines a receiving area in which a pair of traces (traces 650 and 670) is located. Ground 610 extends around the perimeter of and all four sides of the pair of traces. The surrounding or enclosed configuration of ground 610 around the traces 650 and 670 reduce the leakage of signals from traces 650 and 670, which reduces the interference of the signal or signals from connector structure 600 with the signal or signals generated by the adjacent connector structures 500 or 700.

Referring to connector structure 700, it includes a ground 710 that defines an area 725 in which a pair of traces (traces 750 and 770) is located. The pair of traces has four sides that are completely surrounded by ground 710. Ground portion 711 has side portions 714 and 716 that are coupled to side portions 734 and 736, respectively, of ground portion 730 to form an enclosure. The enclosed nature of ground 710 reduces the leakage of signals from traces 750 and 770. This reduction of signal leakage by ground 710 results in less interference of the signal or signals from connector structure 700 with the signal or signals generated by adjacent connector structure 600.

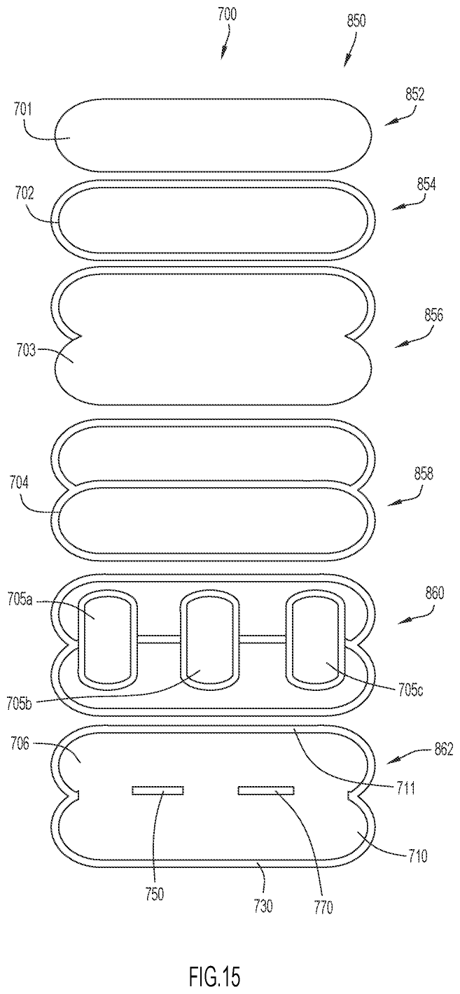

Turning to FIG. 15, manufacturing steps of an exemplary method of manufacturing steps of an interconnect structure according to the disclosed techniques are illustrated. The exemplary method 850 of fabricating connector structure 700 illustrated in FIG. 15 is described. In step 852, a first primary routing 701 is formed in the shape illustrated. In step 854, a plating 702 is applied around the perimeter of the first primary routing 701 and a fill is added. In step 856, a second primary routing 703 is formed in the shape illustrated and is located slightly offset from plated first primary routing 701. In step 858, a plating 704 is placed around the perimeter of the second primary routing 703.

In step 860, several cross routes are formed. In particular, cross routes 705a, 705b, and 705c are formed. In this embodiment, the cross routes 705a, 705b, and 705c are aligned with each other. Cross routes 705a, 705b, and 705c span from first primary routing 701 to second primary routing 703. As a result of the cross routes 705a, 705b, and 705c, traces 750 and 770 are formed between them. In step 862, a resin filling 706 is placed to cover up the first primary routing 701, the second primary routing 703, and the cross routes 705a, 705b, and 705c. The resin filling 706 does not cover the upper ends of the vertical traces 750 and 770. As a result, BGA pads (not shown in FIG. 15) can be connected to the upper ends of the traces. Also shown in FIG. 5 are the various sides of the vertical traces 750 and 770. Ground 710 extends around all of the outer sides of the pair of traces 750 and 770.

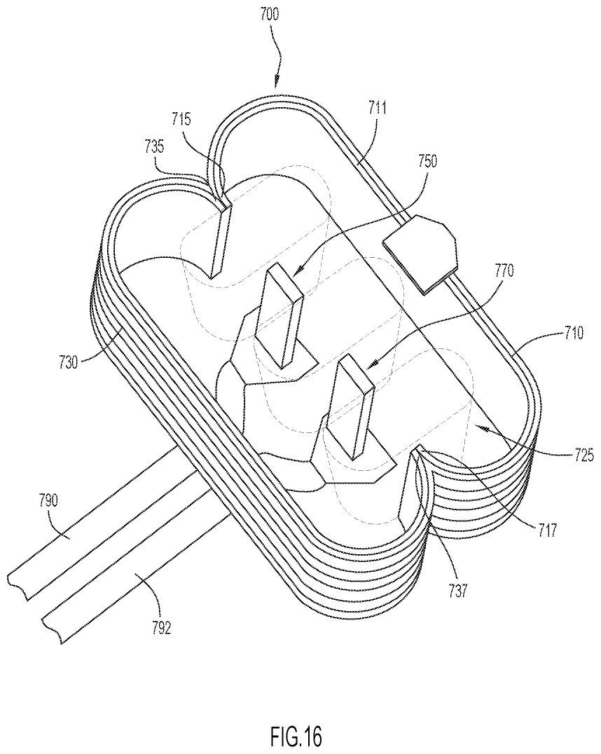

Referring to FIG. 16, a perspective view of an intermediate configuration of an interconnect structure according to the disclosed techniques is illustrated. Portion 711 of ground 710 has opposite ends 715 and 717, and portion 730 of ground 710 has opposite ends 735 and 737. End 715 and end 735 are connected to each other. Similarly, end 717 and end 737 are connected to each other. As a result, portions 711 and 730 form receiving area 725 in which traces 750 and 770 are located. The enclosed receiving area 725 forms an enclosed vertical field. Horizontal trace 790 is connected to a lower end of trace 750, and horizontal trace 792 is connected to a lower end of trace 770.

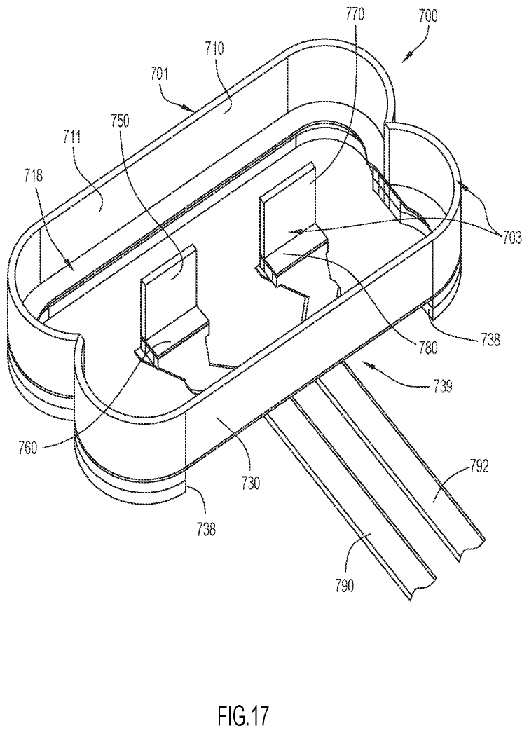

Referring to FIG. 17, a perspective view of another configuration of interconnect structure 700 is illustrated. Portion 711 of ground 710 is formed as part of the first primary routing 701 and its plating 702, and portion 730 of ground 710 as well as traces 750 and 770 are formed as part of the second primary routing 703 and its plating 704. Trace 750 includes a lower portion 760 to which horizontal trace 790 is connected. Similarly, trace 770 includes a lower portion 780 to which horizontal trace 792 is connected.

FIG. 17 shows an example embodiment of the process to remove the short between the ground and signal traces during the plating step. Ground portion 711 includes a first laser and hangout 718 formed on the inner surface of the intermediate portion of ground portion 711. The lower end of ground portion 730 includes a window or opening 739 formed therein that is defined by opposite surfaces 738. Horizontal traces 790 and 792 can pass through the opening 739. In different embodiments, the size, shape, and location of the opening 739 can vary. Accordingly, horizontal traces 790 and 792 can exit from the front, the back, or either of the sides of the connector structure 700 as desired to enable high routing density and any configuration.

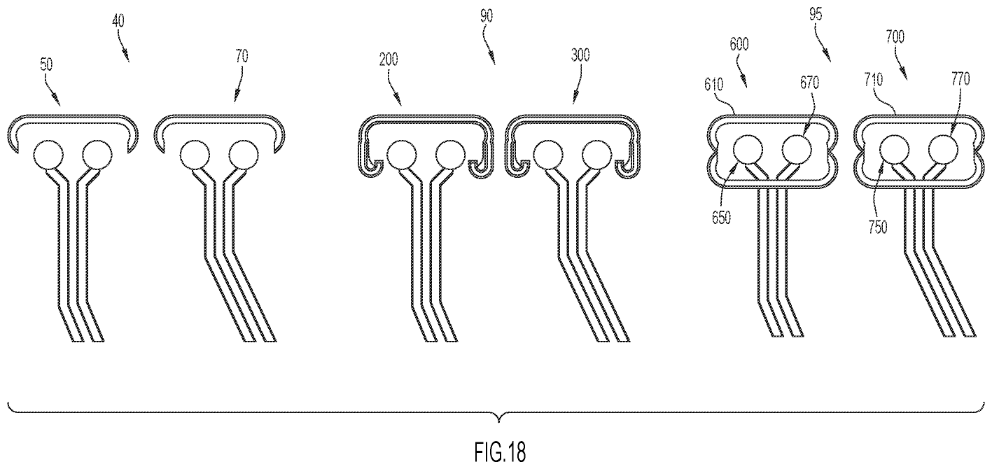

FIG. 18 includes overhead views of the related art interconnect system 40 and the interconnect system 90 that were illustrated in and described relative to FIG. 7. FIG. 18 also includes another embodiment of an interconnect structure according to the disclosed techniques. Connector structure system 95 includes connector structures 600 and 700. Connector structure 600 includes a ground 610 that encloses and surrounds traces 650 and 670. Similarly, connector structure 700 includes a ground 710 that encloses and surrounds traces 750 and 770.

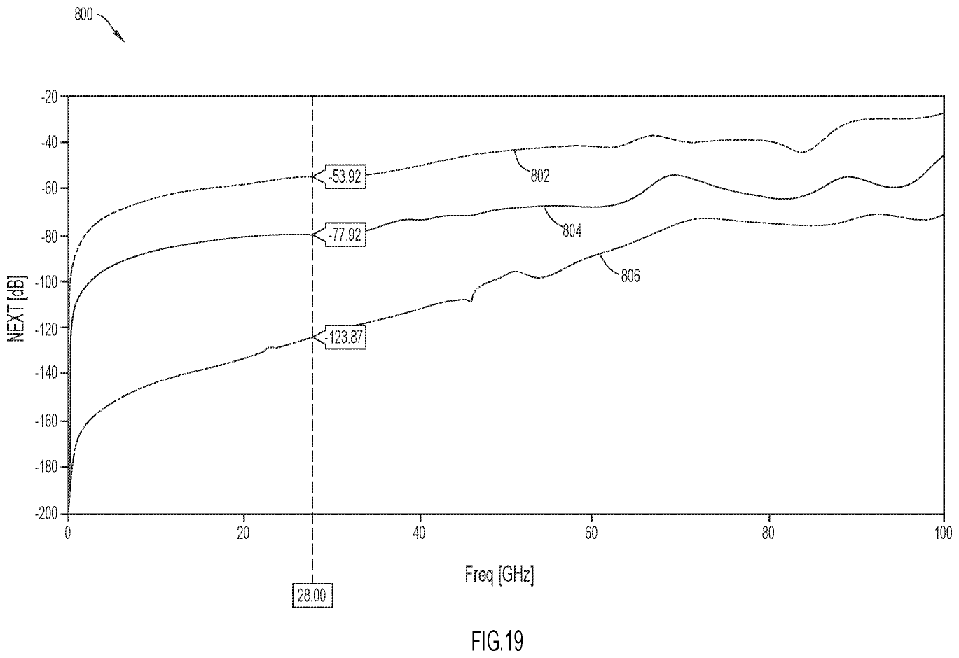

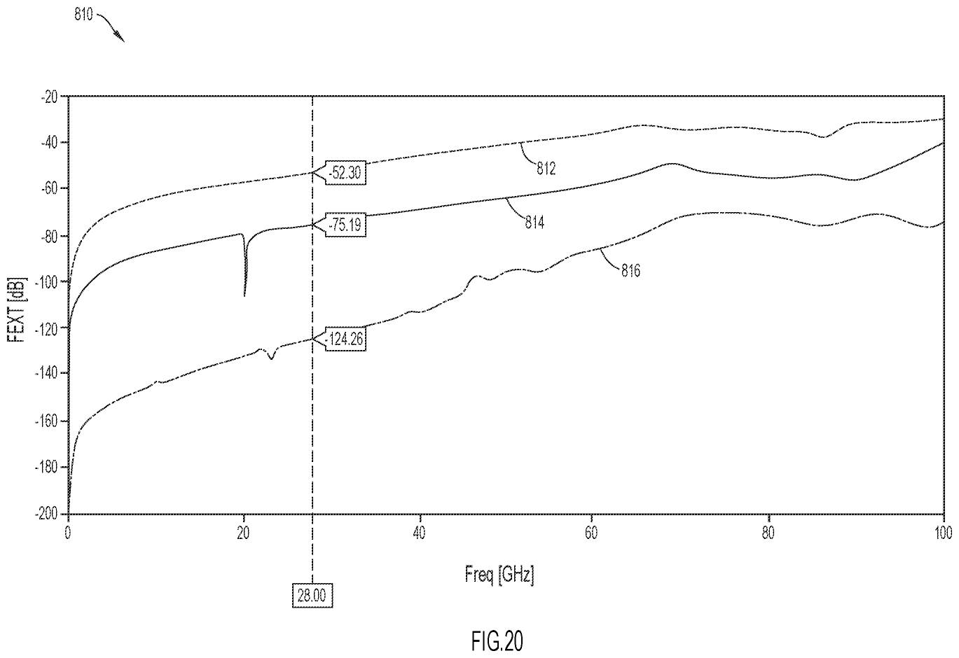

FIGS. 19 and 20 are graphs of signal integrity performance between a related art interconnect structure and multiple example embodiments of an interconnect structure according to the disclosed techniques.

In FIG. 19, the crosstalk performance of NEXT signals in decibels associated with the different interconnect structures is illustrated. In FIG. 19, graph 800 includes a line 802 that represents the performance associated with a related art interconnect structure (such as connector structure 70 in FIG. 18), a line 804 that represents the performance associated with an interconnect structure according to the disclosed techniques (such as connector structure 300 in FIG. 18), and a line 806 that represents the performance associated with another interconnect structure according to the disclosed techniques (such as connector structure 700 in FIG. 18).

In FIG. 19, line 802 corresponds to line 402 in FIG. 8, and line 804 corresponds to line 404 in FIG. 8, each of which are described above. Relative to connector structure 70 and to connector structure 300, connector structure 700 reduces the crosstalk between adjacent connector structures by more than 50 dB as compared to connector structure 70. In particular, connector structure 700 can achieve −75 dB at 100 GHz for a two pair structure. At a frequency of 28 GHZ, the measured NEXT for line 802 is −53.92 dB, for line 804 is −77.92 dB, and for line 806 is −123.87 dB.

In FIG. 20, the crosstalk performance of FEXT signals in decibels associated with the different interconnect structures is illustrated. In FIG. 20, graph 810 includes a line 812 that represents the performance associated with a related art interconnect structure (such as connector structure 70 in FIG. 18), a line 814 that represents the performance associated with an interconnect structure according to the disclosed techniques (such as connector structure 300 in FIG. 18), and a line 816 that represents the performance associated with another interconnect structure according to the disclosed techniques (such as connector structure 700 in FIG. 18).

In FIG. 20, line 812 corresponds to line 412 in FIG. 9, and line 814 corresponds to line 414 in FIG. 9, each of which are described above. Relative to connector structure 70 and to connector structure 300, connector structure 700 also reduces the FEXT crosstalk between adjacent connector structures. At a frequency of 28 GHz, the measured FEXT for line 812 is −52.30 dB, for line 814 is −75.19 dB, and for line 816 is −124.26 dB.

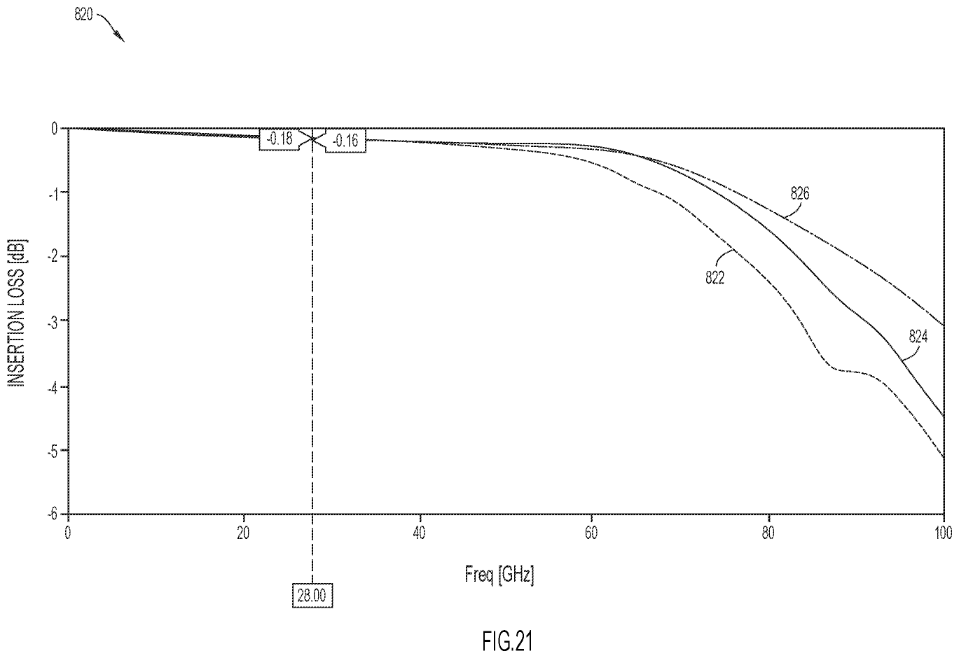

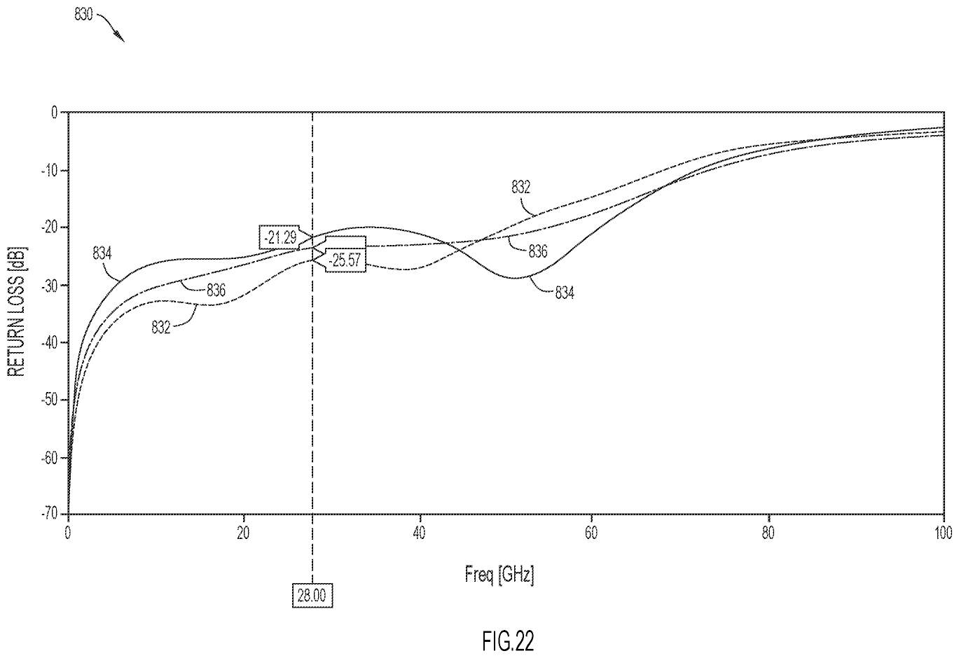

FIGS. 21 and 22 are graphs that show the signal integrity in terms of IL and RL, respectively, for a related art interconnect structure and multiple example embodiments of interconnect structures according to the disclosed techniques

In FIG. 21, the signal integrity in terms of IL in decibels associated with the different interconnect structures is illustrated. Graph 820 includes line 822 that corresponds to line 422 in FIG. 10 for connector structure 70, and line 824 that corresponds to line 424 in FIG. 10 for connector structure 300. Graph 820 also includes line 826 that represents the performance of connector structure 700. As shown, connector structure 700 improves the IL. The IL curve for line 826 is smooth above 60 GHz and the IL above 60 GHZ is improved by approximately 2 dB as compared to convention connector structure 70.

In FIG. 22, the signal integrity in terms of RL in decibels associated with the different interconnect structures is illustrated. Graph 830 includes line 832 that corresponds to line 432 in FIG. 11 for connector structure 70, and line 834 that corresponds to line 434 in FIG. 11 for connector structure 300. Graph 830 also includes line 836 that represents the performance of connector structure 700. As shown, connector structure 700 achieves-10 dB RL up to 70 GHz without any tunings. At a frequency of 28 GHz, the RL for connector structure 700 (line 836) is-21.29 dB.

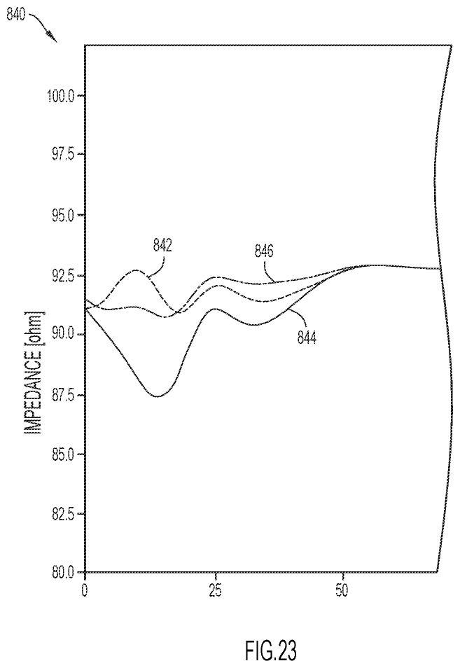

FIG. 23 is a graph 840 of impedance measured for a connector structure 70 (line 842), connector structure 300 (line 844) and connector structure 700 (line 846). The impedance difference between the connector structures 70, 300, and 700 is illustrated.

In summary, the advantages of the disclosed connector structures according to the disclosed techniques include improved signal integrity and improved crosstalk performance.

Accordingly, in some aspects, the techniques described herein relate to an apparatus including: a printed circuit board connector structure, comprising: an outer ground defining a receiving area; and a pair of traces located in the receiving area, the pair of traces collectively having a first side, a second side, a third side, and a fourth side, wherein the outer ground extends around each of the first side, the second side, and the third side of the pair of traces.

In some aspects, the techniques described herein relate to an apparatus, wherein the outer ground extends only around the first side, the second side, and the third side of the traces.

In some aspects, the techniques described herein relate to an apparatus, wherein the outer ground has a first end and a second end opposite its first end, the first end having a curved configuration, the second end having a curved configuration, and each of the first end and the second end reduces any signal from either of the traces from leaving the receiving area.

In some aspects, the techniques described herein relate to an apparatus, wherein the first end of the outer ground extends in a direction toward the second end of the outer ground.

In some aspects, the techniques described herein relate to an apparatus, wherein the outer ground extends around each of the first side, the second side, the third side and the fourth side of the traces.

In some aspects, the techniques described herein relate to an apparatus, wherein each of the pair of traces extends vertically, and a bottom of each of the pair of traces connects with a horizontal trace such that the pair of traces do not extend beyond a horizontal trace connected thereto in a vertical direction.

In some aspects, the techniques described herein relate to an apparatus, wherein each trace carries a different signal.

In some aspects, the techniques described herein relate to an apparatus, wherein each trace carriers a power signal.

In some aspects, the techniques described herein relate to an apparatus including: printed circuit board connector structure, comprising: an outer ground defining a receiving area; a first trace located in the receiving area, the first trace having a first side and a second side opposite to the first side; and a second trace spaced apart from the first trace, the second trace located in the receiving area, the second trace having a third side and a fourth side opposite to the third side, the fourth side of the second trace being proximate to the second side of the first trace, wherein the outer ground extends around the first side of the first trace and around the third side of the second trace.

In some aspects, the techniques described herein relate to an apparatus, wherein the outer ground has a first curved end and a second curved end opposite its first curved end, and each of the first curved end and the second curved end reduces any signal from either of the first trace or the second trace from leaving the receiving area.

In some aspects, the techniques described herein relate to an apparatus, wherein the first curved end of the outer ground extends in a direction toward the second curved end of the outer ground.

In some aspects, the techniques described herein relate to an apparatus, wherein the outer ground extends continuously around the first trace and the second trace.

In some aspects, the techniques described herein relate to an apparatus, wherein each of the first trace and the second trace extends vertically, a bottom of each of the first trace and the second trace connects with a horizontal trace such that the first trace and the second trace do not extend beyond a horizontal trace connected thereto in a vertical direction.

In some aspects, the techniques described herein relate to an apparatus, wherein the first trace and the second trace carry different signals.

In some aspects, the techniques described herein relate to an apparatus including: printed circuit board, comprising: a first connector structure including: a first outer ground defining a first receiving area; and a first pair of vertical traces located in the first receiving area, the first pair of vertical traces collectively having a first side, a second side, a third side, and a fourth side, wherein the first outer ground extends around each of the first side, the second side, and the third side of the first pair of vertical traces; and a second connector structure including: a second outer ground defining a second receiving area; and a second pair of vertical traces located in the second receiving area, the second pair of vertical traces collectively having a fifth side, a sixth side, a seventh side, and an eighth side, wherein the second outer ground extends around each of the fifth side, the sixth side, and the seventh side of the second pair of vertical traces, wherein the first outer ground and the second outer ground reduce any signals leaving the first receiving area and the second receiving area, respectively.

In some aspects, the techniques described herein relate to an apparatus, wherein the first outer ground extends only around the first side, the second side, and the third side of the first pair of vertical traces, and the second outer ground extends only around the fifth side, the sixth side, and the seventh side of the second pair of vertical traces.

In some aspects, the techniques described herein relate to an apparatus, wherein the first outer ground has a first curved end and a second curved end opposite its first curved end, the second outer ground has a third curved end and a fourth curved end opposite its third curved end, and each of the second curved end and the third curved end extending between the first pair of vertical traces and the second pair of vertical traces.

In some aspects, the techniques described herein relate to an apparatus, wherein the first outer ground extends around each of the first side, the second side, the third side and the fourth side of the first pair of vertical traces.

In some aspects, the techniques described herein relate to an apparatus, wherein a bottom of each trace of the first pair of vertical traces connects with a horizontal trace such that each trace of the first pair of vertical traces does not extend beyond its connected horizontal trace in a vertical direction.

In some aspects, the techniques described herein relate to an apparatus, wherein each of the vertical traces carries a different signal.

### VARIATIONS AND IMPLEMENTATIONS

Note that in this Specification, references to various features (e.g., elements, structures, nodes, modules, components, engines, logic, steps, operations, functions, characteristics, etc.) included in “one embodiment,” “example embodiment,” “an embodiment,” “another embodiment,” “certain embodiments,” “some embodiments,” “various embodiments,” “other embodiments,” “alternative embodiment,” and the like are intended to mean that any such features are included in one or more embodiments of the present disclosure, but may or may not necessarily be combined in the same embodiments.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase “at least one of.” “one or more of.” “and/or.” variations thereof, or the like are open-ended expressions that are both conjunctive and disjunctive in operation for any and all possible combination of the associated listed items. For example, each of the expressions “at least one of X, Y and Z.” “at least one of X, Y or Z.” “one or more of X, Y and Z.” “one or more of X, Y or Z” and “X, Y and/or Z” can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms “first,” “second,” “third,” etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, “first X” and “second X” are intended to designate two “X” elements that are not necessarily limited by any order, rank, importance, temporal sequence, or hierarchy of the two elements. Further as referred to herein, “at least one of” and “one or more of” can be represented using the “(s)” nomenclature (e.g., one or more element(s)).

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. A printed circuit board connector structure, comprising:
an outer ground defining a receiving area; and
a pair of traces located in the receiving area, the pair of traces collectively having a first side, a second side, a third side, and a fourth side, wherein the outer ground extends around each of the first side, the second side, and the third side of the pair of traces.

2. The printed circuit board connector structure of claim 1, wherein the outer ground extends only around the first side, the second side, and the third side of the traces.

3. The printed circuit board connector structure of claim 2, wherein the outer ground has a first end and a second end opposite its first end, the first end having a curved configuration, the second end having a curved configuration, and each of the first end and the second end reduces any signal from either of the traces from leaving the receiving area.

4. The printed circuit board connector structure of claim 3, wherein the first end of the outer ground extends in a direction toward the second end of the outer ground.

5. The printed circuit board connector structure of claim 1, wherein the outer ground extends around each of the first side, the second side, the third side and the fourth side of the traces.

6. The printed circuit board connector structure of claim 1, wherein each of the pair of traces extends vertically, and a bottom of each of the pair of traces connects with a horizontal trace such that the pair of traces do not extend beyond a horizontal trace connected thereto in a vertical direction.

7. The printed circuit board connector structure of claim 1, wherein each trace carries a different signal.

8. The printed circuit board connector structure of claim 1, wherein each trace carries a power signal.

9. A printed circuit board connector structure, comprising:
an outer ground defining a receiving area;
a first trace located in the receiving area, the first trace having a first side and a second side opposite to the first side; and
a second trace spaced apart from the first trace, the second trace located in the receiving area, the second trace having a third side and a fourth side opposite to the third side, the fourth side of the second trace being proximate to the second side of the first trace, wherein the outer ground extends around the first side of the first trace and around the third side of the second trace.

10. The printed circuit board connector structure of claim 9, wherein the outer ground has a first curved end and a second curved end opposite its first curved end, and each of the first curved end and the second curved end reduces any signal from either of the first trace or the second trace from leaving the receiving area.

11. The printed circuit board connector structure of claim 10, wherein the first curved end of the outer ground extends in a direction toward the second curved end of the outer ground.

12. The printed circuit board connector structure of claim 9, wherein the outer ground extends continuously around the first trace and the second trace.

13. The printed circuit board connector structure of claim 9, wherein each of the first trace and the second trace extends vertically, a bottom of each of the first trace and the second trace connects with a horizontal trace such that the first trace and the second trace do not extend beyond a horizontal trace connected thereto in a vertical direction.

14. The printed circuit board connector structure of claim 9, wherein the first trace and the second trace carry different signals.

15. A printed circuit board, comprising:
a first connector structure including:
a first outer ground defining a first receiving area; and
a first pair of vertical traces located in the first receiving area, the first pair of vertical traces collectively having a first side, a second side, a third side, and a fourth side, wherein the first outer ground extends around each of the first side, the second side, and the third side of the first pair of vertical traces; and
a second connector structure including:
a second outer ground defining a second receiving area; and
a second pair of vertical traces located in the second receiving area, the second pair of vertical traces collectively having a fifth side, a sixth side, a seventh side, and an eighth side, wherein the second outer ground extends around each of the fifth side, the sixth side, and the seventh side of the second pair of vertical traces, wherein the first outer ground and the second outer ground reduce any signals leaving the first receiving area and the second receiving area, respectively.

16. The printed circuit board of claim 15, wherein the first outer ground extends only around the first side, the second side, and the third side of the first pair of vertical traces, and the second outer ground extends only around the fifth side, the sixth side, and the seventh side of the second pair of vertical traces.

17. The printed circuit board of claim 15, wherein the first outer ground has a first curved end and a second curved end opposite its first curved end, the second outer ground has a third curved end and a fourth curved end opposite its third curved end, and each of the second curved end and the third curved end extending between the first pair of vertical traces and the second pair of vertical traces.

18. The printed circuit board of claim 15, wherein the first outer ground extends around each of the first side, the second side, the third side and the fourth side of the first pair of vertical traces.

19. The printed circuit board of claim 15, wherein a bottom of each trace of the first pair of vertical traces connects with a horizontal trace such that each trace of the first pair of vertical traces does not extend beyond its connected horizontal trace in a vertical direction.

20. The printed circuit board of claim 15, wherein each of the vertical traces carries a different signal.
